(19) United States
(12) Patent Application Publication
(10) Pub. No.: US 2017/0097386 A1
(43) Pub. Date: Apr. 6, 2017

(54) APPARATUS AND METHODS FOR MEASURING ELECTRICAL CURRENT

(71) Applicant: Voltech Instruments, Ltd., Milton Park, Abingdon, Oxfordshire (GB)

(72) Inventors: John Stewart FORD, Sanibel, FL (US); Lionel IND, Headington (GB)

(73) Assignee: Voltech Instruments, Ltd., Milton Park, Abingdon, Oxfordshire (GB)

(21) Appl. No.: 15/128,505

(22) PCT Filed: Mar. 16, 2015
(86) PCT No.: PCT/GB2015/050759

§ 371 Date: Sep. 23, 2016

(30) Foreign Application Priority Data
Mar. 25, 2014 (GB) 1405332.6

(51) Int. Cl. G01R 31/02; G01R 19/00

(52) U.S. Cl. CPC G01R 31/027; G01R 19/0092

(57) ABSTRACT

Methods and apparatus are disclosed for measuring an electrical current, particularly an AC electrical current, for example to measure a frequency response of a transformer. In a disclosed arrangement, a connection is made of a current input terminal for receiving a current to be measured to an input terminal of a differential amplifier via a portion of a resistive network. The resistive network holds the current input terminal at a ground voltage and the two input terminals of the amplifier at a common finite voltage above the ground voltage. The amplifier provides as output a measure of the current to be measured.

The present invention relates to apparatus and methods for measuring electrical current. The invention is particularly applicable to measuring an alternating current for the purpose of measuring the impedance of a device to be tested. The device to be tested may be an electrical transformer for example.

Impedance meters are known in which a voltage is applied across a device to be tested and a current measuring circuit obtains a measure of the resulting current through the device. Such devices can be simple to construct but tend to be vulnerable to errors arising due to a portion of the current to be measured flowing into stray or parasitic impedances (for example to ground) rather than contributing to a voltage that is intended to be indicative of the current through the device to be tested.

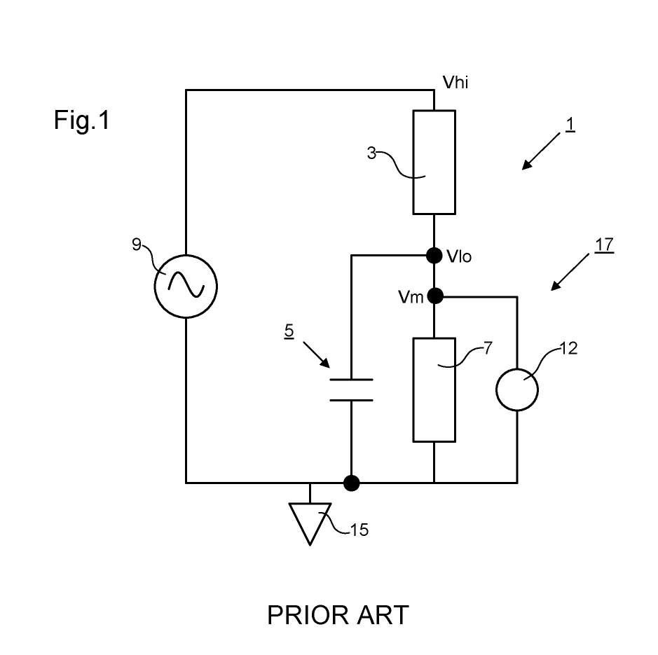

FIG. 1 depicts an example circuit 1 for measuring the impedance of a device 3 to be tested. The circuit 1 comprises an AC voltage source 9 configured to drive an AC current though the device 3. The sizes and direction of the AC current through the device 3 are determined by the potential difference across the device 3, Vhi−Vlo. A current measuring circuit 17 is provided for measuring the current through the device 3. The impedance of the device 3 can be derived from the measured current. The current measuring circuit 17 measures a voltage drop associated with the current exiting the device 3 and flowing through a reference resistor 7 to ground 15. The voltage drop Vm across the reference resistor 7 is measured by a voltmeter 12. As explained above, however, a stray impedance 5 may be present, which prevents the voltage Vm measured across the reference resistor 7 from being an accurate representation of the voltage Vlo at the low voltage side of the device 3 to be tested. This effect leads to inaccuracies in the current measurement.

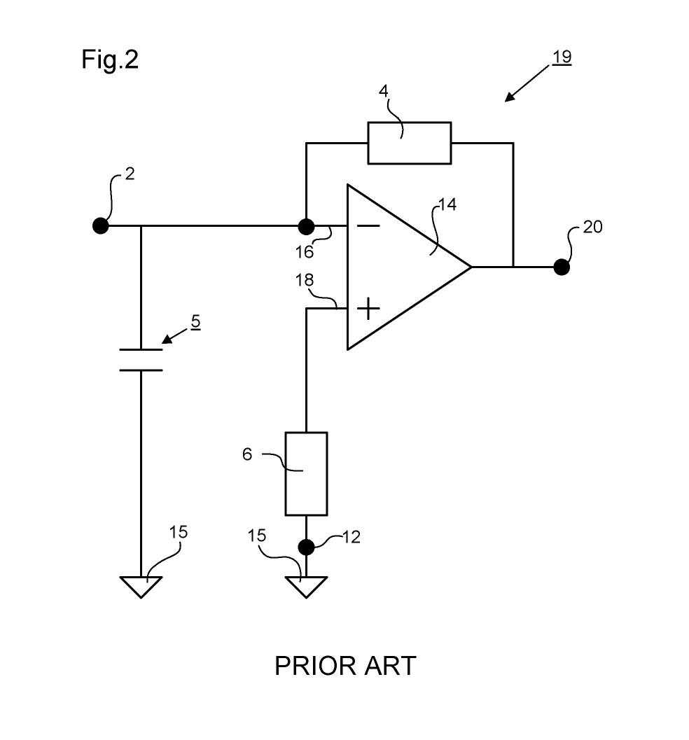

It is known to try to improve the accuracy of the current measurement relative to circuits of the type shown in FIG. 1 by using a current measuring circuit 19 of the type shown in FIG. 2. Here, the current measuring circuit 19 comprises a current input terminal 2 for receiving an electrical current to be tested. A ground terminal 12 is provided for connection to a ground voltage 15. As discussed above, it is expected that there will be a stray impedance 5, for example a stray capacitance (as shown), acting between the current input terminal 2 and ground 15. An operational amplifier 14 is provided. The operational amplifier 14 has an inverting input 16, a non-inverting input 18 and an output 20. A resistor 4 is connected in a negative feedback loop from the output 20 to the inverting input 16. The connection of the non-inverting input 18 to ground 15 means that the potential of the non-inverting input 16 is also pulled to ground (by the amplifier 14). This means that there is no potential difference across the stray impedance 5 and substantially no current passes through the stray impedance. Therefore substantially all of the current arriving at the current input terminal 2 must pass through the resistor 4 and contribute to the voltage output by output 20. Errors due to current flowing through the stray impedance 5 in the manner discussed above with reference to FIG. 1 are therefore substantially eliminated. However, the direct connection of the input 16 to the current input terminal 2 means that any noise at the current input terminal 2 is input directly to the amplifier 14, which limits the sensitivity of the circuit. Furthermore, the stray impedance 5 and the resistor 4 form a resonant circuit or “pole”, which causes the amplifier to be unstable. The instability can be reduced or removed by adjusting the frequency response of the amplifier 14 to avoid the pole (e.g. by “rolling off” the response of the amplifier). However, this limits the range of frequencies within which the amplifier is effective. If the stray impedance comprises a large capacitive component, the maximum frequency at which the current measuring circuit 19 can operate effectively may be severely limited.

Similar problems arise when transimpedance amplifiers (TIAs) are used to translate the current output of sensors such photodiodes to a voltage signal. TIAs are often based for example on a circuit comprising an operational amplifier with a feedback resistor from the output to the inverting input. The sensor is connected to the inverting input. Capacitive characteristics of the sensors can cause resonances (“poles”) that can cause instabilities in such circuits unless compensatory steps are taken. These steps may comprise for example the addition of compensating capacitors in parallel with the feedback resistor or adjustment of the frequency response of the operational amplifier. Such circuits can therefore become complex to design and build.

It is an object of the present invention to provide apparatus and methods for measuring current that at least partially overcome one or more of the problems with the prior art discussed above.

According to an aspect of the invention, there is provided a current measuring circuit comprising: a current input terminal for receiving an electrical current to be tested; a ground terminal for connection to a ground voltage; and a differential amplifier having first and second input terminals and an output terminal, wherein feedback is provided between the output terminal and both of the first and second input terminals in such a way as to maintain the current input terminal at the ground voltage and the first and second input terminals of the differential amplifier at a common finite voltage above the ground voltage.

Maintaining the current input terminal at ground voltage avoids errors caused by current flow to ground from the current input terminal through stray impedances. Simultaneously providing feedback that maintains the input terminals of the differential amplifier at a common finite voltage above the ground voltage reduces the extent to which noise at the current input terminal can reduce the sensitivity of the circuit and avoids instabilities caused by resonances involving stray impedances without requiring complex circuit design and the additional of extra components such as capacitors.

In an embodiment, the differential amplifier comprises an operational amplifier.

In an embodiment, the feedback is provided by a network comprising first, second, third and fourth resistive components. The first resistive component is connected in series between the current input terminal and the first input terminal of the amplifier. The second resistive component is connected in series between the first input terminal and the output terminal of the amplifier. The third resistive component is connected in series between the ground terminal and the second input terminal of the amplifier. The fourth resistive component is connected in series between the second input terminal and the output terminal of the amplifier. The ratio of the resistance of the first resistive component to the resistance of the second resistive component is equal to the ratio of the resistance of the third resistive component to the resistance of the fourth resistive component. This approach provides a particularly simple and reliable way of ensuring that the current input terminal is maintained at the ground voltage and the first and second input terminals of the differential amplifier are maintained at a common finite voltage above the ground voltage.

In an aspect, there is provided an apparatus for characterizing a component, comprising: a current measuring circuit according to an embodiment; an AC power source; and first and second component receiving terminals for connection to terminals of the component to be characterized, wherein the first component receiving terminal is connected to a high voltage line driven by the AC power source; the second component receiving terminal is connected to the current input terminal of the current measuring circuit.

In an aspect, there is provided a method of measuring current, comprising: connecting a current input terminal for receiving a current to be measured to one of two input terminals of a differential amplifier via a portion of a network comprising resistive components; holding the current input terminal at a ground voltage and the two input terminals of the amplifier at a common finite voltage above the ground voltage; providing an output from the amplifier as a measure of the current to be measured.

Embodiments of the invention will now be described, by way of example only, with reference to the accompanying drawings in which corresponding reference symbols indicate corresponding parts, and in which:

FIG. 1 depicts a prior art circuit for measuring current flow through a device to be tested;

FIG. 2 depicts a prior art current measurement circuit comprising an operational amplifier to reduce errors from stray impedances;

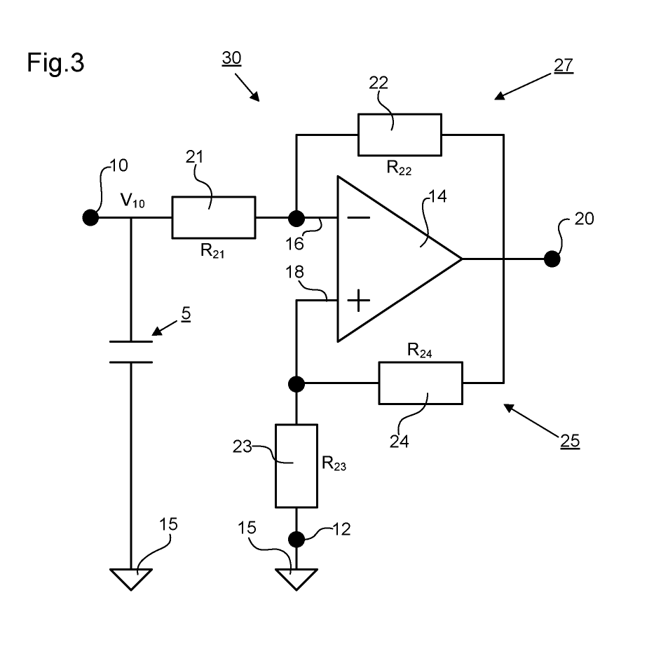

FIG. 3 depicts a current measuring circuit according to an embodiment;

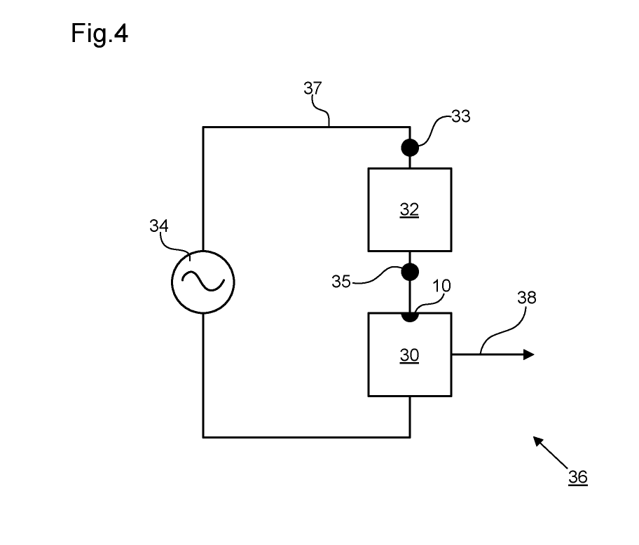

FIG. 4 depicts an apparatus for measuring the frequency response of a transformer.

FIG. 3 depicts a current measuring circuit 30 according to an embodiment. The circuit is particularly suitable for measuring AC currents, for example above 10 kHz, preferably in the range of about 40 kHz to several hundred kHz or more than 1 MHz. The circuit comprises a current input terminal 10 for receiving an electrical current to be tested. A ground terminal 12 is provided for connection to a ground voltage 15. As discussed above, it is also expected that there will be a stray impedance 5, for example a stray capacitance (as shown), acting between the current input terminal 10 and ground 5. A differential amplifier 14 is provided. The differential amplifier 14 has first and second input terminals 16 and 18 and an output terminal 20. In an embodiment, the differential amplifier is an operational amplifier. In an embodiment, the first input terminal 16 of the amplifier is an inverting input and the second input terminal 18 of the amplifier is a non-inverting input.

In an embodiment a network providing feedback between the output terminal 20 and both of the first and second input terminals 16 and 18 is provided. In the embodiment shown, the feedback comprises a positive feedback loop 25 and a negative feedback loop 27. The feedback is configured so as to maintain the current input terminal 10 at the ground voltage 15 and the first and second input terminals 16 and 18 at a common finite voltage above the ground voltage 15.

Maintaining the current input terminal 10 at the ground voltage ensures that no significant current flows through the stray impedance 5, thereby minimizing errors in the measurement of the current being supplied to the current input terminal 10. Maintaining the first and second input terminals 16 and 18 at a common finite voltage above the ground voltage means that the first and second input terminals 16 and 18 are not connected directly to the stray impedance. Direct connection of the stray impedance to one of the inputs terminals 16 and 18 can cause instabilities unless the frequency response of the amplifier 14 is modified to avoid the resonance frequency associated with the stray impedance. Avoiding having to make such modifications to the amplifier 14 means that the amplifier can measure current accurately over a wider range of frequencies and/or with improved stability. Furthermore, isolating the amplifier 14 from the current input terminal 10 in this manner reduces the extent to which noise at the current input terminal enters the input terminals 16 and 18, thus improving the sensitivity of the circuit.

In an embodiment, the network comprises a first resistive component 21 (e.g. a resister), a second resistive component 22 (e.g. a resistor), a third resistive component 23 (e.g. a resistor) and a fourth resistive component 24 (e.g. a resistor). In other embodiments the network may comprise fewer or more resistive components and/or other components, such as capacitive components. One or more of the resistive or capacitive components may have properties that are not purely resistive or capacitive. Such components may have a combination of resistive, capacitive and/or inductive characteristics.

In an embodiment, the first resistive component 21 is connected in series between the current input terminal 10 and the first input terminal 16 of the amplifier 14. Thus, the first resistive component 21 isolates the current input terminal 10 from the first input terminal 16 of the amplifier 14 and ensures that they are maintained at different potentials.

In an embodiment, the second resistive component 22 is connected in series between the first input terminal 16 and the output terminal 20 of the amplifier 14, in this case forming the negative feedback loop 27. The third resistive component 23 is connected in series between the ground terminal 12 and the second input terminal 18 of the amplifier 19. The fourth resistive component 24 is connected in series between the second input terminal 18 and the output terminal 20 of the amplifier 14, in this case forming the positive feedback loop 25. The ratio of the resistance of the first resistive component 21 to the resistance of the second resistive component 22 is arranged to be equal to the ratio of the resistance of the third resistive component 23 to the resistance of the fourth resistive component 24. This arrangement thus acts to maintain the current input terminal 10 at the ground voltage 15 and the first and second input terminals 16 and 18 of the differential amplifier 14 at a common finite voltage above the ground voltage 15. This is explained below:

Referring to the resistances marked on FIG. 3, if the voltage at the current input terminal 10 is to be zero (ground) as desired, assuming the amplifier inputs 16 and 18 are held at the same potential by the amplifier and that the input impedance can be assumed to be infinite, the following expression must be satisfied:

$$\frac{{R}_{21}}{{R}_{21} + {R}_{22}} = \frac{{R}_{23}}{{R}_{23} + {R}_{24}}$$

This expression is derived by observing that the potential divider formed by the resistive components 21 and 22 must yield a voltage at input terminal 16 that is the same as the voltage at input terminal 18 yielded by the potential divider formed by resistive components 23 and 24. From this expression it can easily be derived that:

$$\frac{{R}_{21}}{{R}_{22}} = \frac{{R}_{23}}{{R}_{24}}$$

Therefore, in order that the voltage at the current input terminal 10 is zero it is necessary that the ratio of the resistance R₂₁ of the first resistive component 21 to the resistance R₂₂ of the second resistive component 22 is arranged to be equal to the ratio of the resistance R₂₃ of the third resistive component 23 to the resistance R₂₄ of the fourth resistive component 24.

In an embodiment, the current measuring circuit 30 is used in an apparatus 36 for characterizing a component 32, for example measuring the frequency response of a transformer. A schematic depiction of such an arrangement is shown in FIG. 4. The apparatus 26 comprises an AC power source 24. The apparatus 36 comprises first and second component receiving terminals 33 and 35 for connection to terminals of the component 32 to be characterized. The first component receiving terminal 33 is connected to a high voltage line 37 driven by the AC power source 34. The second component receiving terminal 35 is connected to the current input terminal 10 of the current measuring circuit 30. The current measuring circuit provides an output 38 indicative of the current through the component 32, derived from the output terminal 20 of the amplifier 14. The apparatus 36 can thus be used as an impedance meter, for example as part of an LCR meter, or a transformer tester.

In an embodiment, the current measuring circuit 30 is used to measure the current through a sensor, such as a photodiode, in order to measure an output from the sensor. The current measuring circuit 30 may provide a voltage output and thereby operate as a transimpedance amplifier.

1. A current measuring circuit comprising:
a current input terminal for receiving an electrical current to be tested;
a ground terminal for connection to a ground voltage; and
a differential amplifier having first and second input terminals and an output terminal, wherein
feedback is provided between the output terminal and both of the first and second input terminals in such a way as to maintain the current input terminal at the ground voltage and the first and second input terminals of the differential amplifier at a common finite voltage above the ground voltage.

2. The circuit according to claim 1, wherein the feedback is provided via a network comprising first, second, third and fourth resistive components.

3. The circuit according to claim 2, wherein the first resistive component is connected in series between the current input terminal and the first input terminal of the amplifier.

4. The circuit according to claim 3, wherein:
the second resistive component is connected in series between the first input terminal and the output terminal of the amplifier;
the third resistive component is connected in series between the ground terminal and the second input terminal of the amplifier, and
the fourth resistive component is connected in series between the second input terminal and the output terminal of the amplifier; wherein
the ratio of the resistance of the first resistive component to the resistance of the second resistive component is equal to the ratio of the resistance of the third resistive component to the resistance of the fourth resistive component.

5. The circuit according to claim 1, wherein the network further comprises one or more capacitive components.

6. The circuit according to claim 1, wherein:
the first input terminal of the amplifier is an inverting input and the second input terminal of the amplifier is a non-inverting input.

7. The circuit according to claim 1, wherein:
the amplifier is an operational amplifier.

8. The circuit according to claim 1, configured to measure AC electrical currents.

9. The circuit according to claim 8, wherein the AC electrical currents have frequencies above 10 kHz.

10. An apparatus for characterizing a component, comprising:
a current measuring circuit according to claim 1;
an AC power source; and
first and second component receiving terminals for connection to terminals of the component to be characterized, wherein
the first component receiving terminal is connected to a high voltage line driven by the AC power source;
the second component receiving terminal is connected to the current input terminal of the current measuring circuit.

11. The apparatus according to claim 10, wherein the component is a transformer.

12. A transimpedance amplifier for converting a current output from a sensor into a voltage output, comprising a current measuring circuit according to claim 1.

13. A method of measuring current, comprising:
connecting a current input terminal for receiving a current to be measured to one of two input terminals of a differential amplifier via a portion of a network comprising resistive components;
holding the current input terminal at a ground voltage and the two input terminals of the amplifier at a common finite voltage above the ground voltage;
providing an output from the amplifier as a measure of the current to be measured.

14. A method of characterizing a component, comprising:
applying an AC voltage across the component;
using the method of claim 13 to measure the resulting current flowing through the component.

15. The method according to claim 14, wherein the component is a transformer.

16. (canceled)

17. (canceled)
